(19) United States
(12) Patent Application Publication
(10) Pub. No.: US 2023/0171953 A1
(43) Pub. Date: Jun. 1, 2023

(54) SEMICONDUCTOR DEVICE AND METHOD FOR FABRICATING THE SAME

(71) Applicant: SK hynix Inc., Gyeonggi-do (KR)

(72) Inventor: Jung Sam KIM, Gyeonggi-do (KR)

(21) Appl. No.: 17/736,714

(22) Filed: May 4, 2022

(30) Foreign Application Priority Data
Nov. 26, 2021 (KR) 10-2021-0165724

(51) Int. Cl. H01L 27/108

(52) U.S. Cl. CPC H01L 27/10897; H01L 27/10814; H01L 27/10823; H01L 27/10876; H01L 27/10885; H01L 27/10894

(57) ABSTRACT

Embodiments of the present invention provides a semiconductor device including a reservoir capacitor capable of increasing the surface area of the capacitor by disposing a first electrode having a pillar shape between a substrate and a second electrode and a method for fabricating the same. According to an embodiment of the present invention, the reservoir capacitor comprises: a substrate; a first electrode having a pillar shape and disposed over the substrate; a first dielectric layer disposed between the substrate and the first electrode; a second electrode disposed over the substrate and the first electrode and covering a side surface and a top surface of the first electrode; a second dielectric layer disposed between the first electrode and the second electrode; and a third dielectric layer disposed between the substrate and the second electrode.

### CROSS-REFERENCE TO RELATED APPLICATIONS

The present application claims priority to Korean Patent Application No. 10-2021-0165724, filed on Nov. 26, 2021, which is incorporated herein by reference in its entirety.

### BACKGROUND

### 1. Field

The present invention relates to a method of fabricating a semiconductor device, and more particularly, to a semiconductor device including a reservoir capacitor and a method of fabricating the same.

### 2. Description of the Related Art

In semiconductor integrated circuit devices, high integration, low voltage, and high speed are major variables that determine the performance of semiconductor integrated circuit devices. Such a semiconductor integrated circuit device requires a low voltage and at the same time various levels of power. However, as is well known, when power is supplied into a semiconductor integrated circuit device, noise may be created, and the noise may change the signal transmission characteristics of the device, including, for example, the amount of delay.

Therefore, a capacitor, for example, a reservoir capacitor, for removing noise, is formed in the peripheral region of the semiconductor integrated circuit device.

### SUMMARY

Embodiments of the present invention provide a semiconductor device including an improved reservoir capacitor having an increased surface area for improved noise suppression. The capacitor may employ a pillar-shaped first electrode disposed between a substrate and a second electrode. Embodiments of the present invention also provide a method of fabricating the semiconductor device.

According to an embodiment of the present invention, a reservoir capacitor comprises: a substrate; a first electrode having a pillar shape and disposed over the substrate; a first dielectric layer disposed between the substrate and the first electrode; a second electrode disposed over the substrate and the first electrode and covering a side surface and a top surface of the first electrode; a second dielectric layer disposed between the first electrode and the second electrode; and a third dielectric layer disposed between the substrate and the second electrode.

According to an embodiment of the present invention, a reservoir capacitor comprises: a substrate including an active region defined by a device isolation layer and the device isolation layer; a plurality of trenches formed in the substrate and spaced apart from each other; a first dielectric layer covering a bottom surface and a sidewall of the trenches; a plurality of first electrodes partially buried in the trenches over the first dielectric layer and having a pillar shape protruding above the substrate; a second dielectric layer covering top surface and side surface of each of the first electrodes; a third dielectric layer covering a portion of the substrate exposed between the first electrodes; and a second electrode formed over the second and third dielectric layers.

According to an embodiment of the present invention, a semiconductor device comprises: a substrate including a cell region and a peripheral circuit region; a bit line structure including a bit line contact plug over the substrate of the cell region; a first electrode having a pillar shape and disposed over the substrate of the peripheral circuit region; a second electrode disposed over the substrate and the first electrode in the peripheral circuit region and covering a side surface and a top surface of the first electrode; a second dielectric layer disposed between the first electrode and the second electrode; and a third dielectric layer disposed between the substrate and the second electrode.

According to an embodiment of the present invention, a method of fabricating a semiconductor device, the method comprises: forming a capping layer over a substrate, the substrate including a cell region and a peripheral circuit region; forming a bit line contact hole exposing the substrate by penetrating through the capping layer of the cell region and a peripheral trench exposing the substrate by penetrating through the capping layer of the peripheral circuit region; forming a preliminary bit line contact plug and a first electrode by gap-filling a conductive material in the bit line contact hole and the peripheral trench; forming a reservoir capacitor over the substrate of the peripheral circuit region, the reservoir capacitor including the first electrode having a pillar shape; and forming a bit line structure over the substrate of the cell region, the bit line structure including a bit line contact plug.

The present invention has the effect of improving the capacitance by increasing the surface area of a reservoir capacitor. This invention has the effect of improving the reliability of the semiconductor device by improving the capacitance of the reservoir capacitor.

These and other features and advantages of the present invention will become apparent to the skilled person from the following detailed description of example embodiments of the present invention in conjunction with the following drawings.

### BRIEF DESCRIPTION OF THE DRAWINGS

FIG. 1 is a perspective view illustrating a reservoir capacitor of a semiconductor device according to an embodiment of the present invention.

FIG. 2 is a cross-sectional view illustrating a reservoir capacitor of a semiconductor device according to an embodiment of the present invention.

FIG. 3 is a plan view illustrating a semiconductor device according to an embodiment of the present invention.

FIG. 4 is a cross-sectional view illustrating a semiconductor device according to an embodiment of the present invention.

FIGS. 5A to 18B are plan views and cross-sectional views illustrating a method of fabricating a semiconductor device according to an embodiment of the present invention.

### DETAILED DESCRIPTION

Various embodiments described herein will be described with reference to cross-sectional views, plan views and block diagrams, which are ideal schematic views of the present invention. Therefore, the structures of the drawings may be modified due to fabricating technology and/or tolerances. Various embodiments of the present invention may not be limited to the specific structures shown in the drawings, but may include any changes in the structures that may be produced according to the fabricating process. Also, any regions and shapes of regions illustrated in the drawings, are intended to illustrate specific examples of structures of regions of the various elements, and are not intended to limit the scope of the invention. Sizes and relative sizes of components shown in the drawings may be exaggerated for clarity of description. Like reference numerals refer to like elements throughout, and “and/or” includes each and every combination of one or more of the recited items. In this specification, the singular also includes the plural unless otherwise specified in the phrase.

A semiconductor device according to an embodiment of the present invention may include a reservoir capacitor disposed in a peripheral circuit region of the semiconductor device. The reservoir capacitor may also be referred to as a ‘decoupling capacitor.’ The reservoir capacitor is a device for filtering noise existing between various operating voltages such as, for example, a positive supply voltage VDD and a ground voltage VSS. The higher the capacity of the reservoir capacitor, the more stable the operating voltage can be supplied.

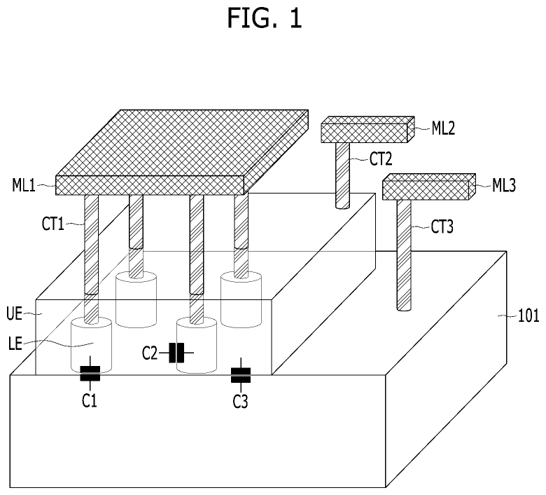

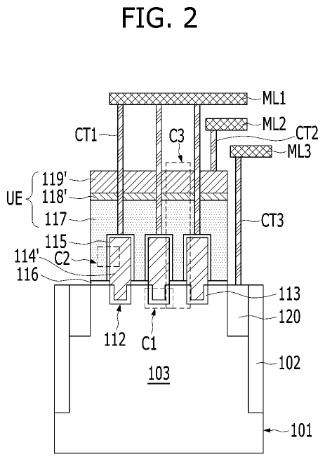

FIG. 1 is a perspective view illustrating a reservoir capacitor of a semiconductor device according to an embodiment of the present invention. FIG. 2 is a cross-sectional view illustrating a reservoir capacitor of a semiconductor device according to an embodiment of the present invention. The same reference numerals in FIGS. 1 and 2 indicate the same structures.

As shown in FIGS. 1 and 2, the reservoir capacitor according to the present embodiment may include a substrate 101 including a plurality of trenches 112, a first electrode (LE)/114′ having a pillar shape protruding above the substrate and partially buried in the trenches 112, a first dielectric layer 113 interposed between the substrate 101 and the first electrode LE 114′, a second electrode structure (UE)/117/118′/119′ disposed over the substrate 101 and the first electrode (LE)/114′ and covering a sidewall and an top surface of the first electrode (LE)/114′, a second dielectric layer 115 interposed between the first electrode (LE)/114′ and the second electrode structure (UE)/117/118′/119′, and a third dielectric layer 116 interposed between the substrate 101 and the second electrode structure (UE)/117/118′/119′. In addition, the reservoir capacitor may include first to third interconnections ML1, ML2, and ML3 for applying a voltage to the substrate 101 and to each electrode. Each interconnection may be electrically connected to the substrate 101 and/or to each electrode through first to third contacts CT1, CT2, and CT3.

The substrate 101 may be a material suitable for semiconductor processing. The substrate 101 may include a semiconductor substrate. The substrate 101 may be made of a material containing silicon. The substrate 101 may include silicon, monocrystalline silicon, polysilicon, amorphous silicon, silicon germanium, monocrystalline silicon germanium, polycrystalline silicon germanium, carbon doped silicon, combinations thereof, or multiple layers thereof. The substrate 101 may include other semiconductor materials such as germanium. The substrate 101 may include a III/V group semiconductor substrate, for example, a compound semiconductor substrate such as gallium arsenide (GaAs). The substrate 101 may include a silicon on insulator (SOI) substrate.

The first dielectric layer 113 may be disposed between the substrate 101 and the first electrode (LE)/114′. The first dielectric layer 113 may include silicon oxide. The first dielectric layer 113 may be formed through a thermal oxidation process. The first dielectric layer 113 may be formed to cover side surfaces and a bottom surface of the trench 112. The first dielectric layer 113 formed on the side surfaces of the trench 112 may have an inclined profile that increases in thickness toward the bottom surface of the trench 112.

The first electrode (LE)/114′ may be disposed between the substrate 101 and the second electrode structure (UE)/117/118′/119′. The first electrode (LE)/114′ may be configured to include a plurality of first electrodes (LE) 114′ which are spaced apart from each other at a regular interval. The first electrode (LE)/114′ may be spaced apart from the substrate 101 and the second electrode structure (UE)/117/118′/119′ by the first and second dielectric layers 113 and 115, respectively.

The second dielectric layer 115 may be disposed between the first electrode LE/114′ and the second electrode structure (UE)/117/118′/119′. The third dielectric layer 116 may be disposed between the substrate 101 and the second electrode structure (UE)/117/118′/119′. The second dielectric layer 115 and the third dielectric layer 116 may include silicon oxide. The second dielectric layer 115 and the third dielectric layer 116 may be simultaneously formed. The second dielectric layer 115 and the third dielectric layer 116 may be formed through a thermal oxidation process.

The second electrode structure (UE)/117/118′/119′ may include a conductive material. The second electrode structure (UE)/117/118′/119′ may include a stacked structure of a semiconductor material and a metal material.

The first to third interconnections ML1, ML2, and ML3 may be disposed at a higher level than the second electrode structure (UE)/117/118′/119′. The first to third interconnections ML1, ML2, and ML3 may be disposed at the same level or different levels. The first interconnection ML1 may be connected to the plurality of first electrodes 114′. The first contacts CT1 may electrically connect the first interconnection ML1 and the plurality of first electrodes 114′. The second interconnection ML2 may be connected to the second electrode structure 117/118′/119′. The second contact CT2 may electrically connect the second electrode structure 117, 118′ and 119′ and the second interconnection ML2. The third interconnection ML3 may be connected to the substrate 101. The third contact CT3 may electrically connect the third interconnection ML3 and the substrate 101.

Impurity regions 120 may be formed in the substrate 101 on both sides of the reservoir capacitor.

As a comparative example, the capacitance of a conventional planar MOS capacitor is composed of a substrate, a second electrode having a planar structure formed on the substrate, and a dielectric layer disposed between the substrate and the second electrode. In contrast, in the reservoir capacitor according to the present embodiment, the pillar-shaped first electrodes (LE)/114′ are formed between the substrate 101 and the second electrode structure (UE) 117, 118′, 119′. Therefore, the surface area of the capacitor may increase, thereby increasing the capacitance.

More specifically, the capacitance of the reservoir capacitor according to the present embodiment may be the sum of a first capacitance C1 through the substrate 101, the first dielectric layer 113, and the first electrode (LE)/114′, a second capacitance C2 through the second dielectric layer 115 and the second electrode structure (UE)/117/118′/119′; and a third capacitance C3 through the substrate 101, the third dielectric layer 116, and the second electrode structure (UE) 117, 118′, 119′.

Although the reservoir capacitor of the present embodiment shows three or four first electrodes (LE) 114′, the present invention is not limited thereto. The number of first electrodes included in one reservoir capacitor, the spacing between the first electrodes, and the height and width of each first electrode may be adjusted, as necessary.

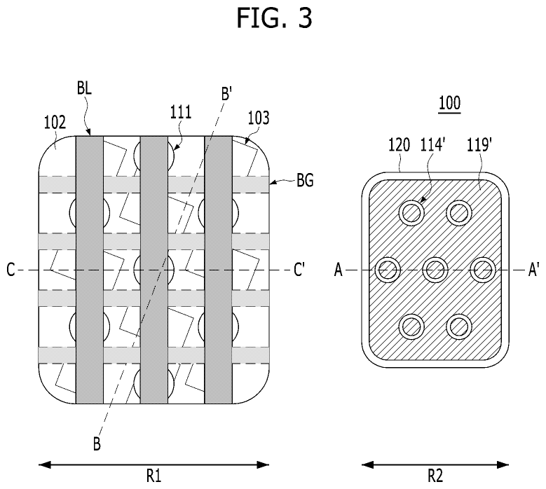

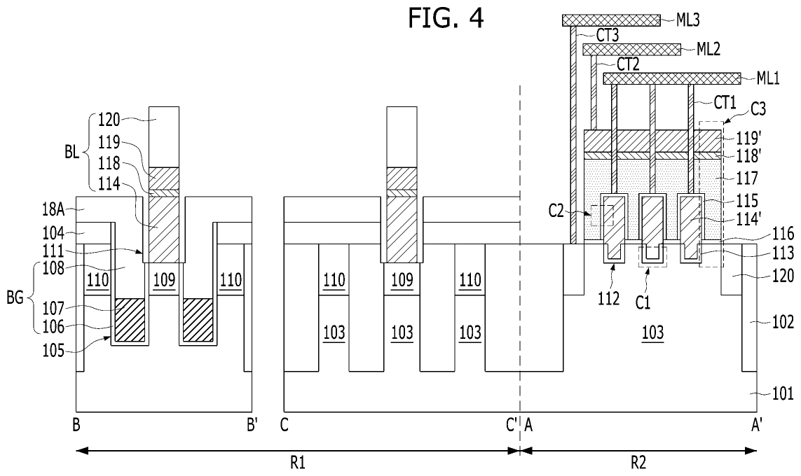

FIG. 3 is a plan view illustrating a semiconductor device according to an embodiment of the present invention. FIG. 4 is a cross-sectional view illustrating a semiconductor device according to an embodiment of the present invention. FIG. 4 is a cross-sectional view taken along lines A-A′, B-B′ and C-C′ of FIG. 3.

Referring to FIG. 3, the semiconductor device 100 may include a cell region R1 in which a plurality of memory cells are formed and a peripheral circuit region R2 in which a reservoir capacitor is formed. The cell region R1 and the peripheral circuit region R2 may be spaced apart by a device isolation layer 102 (refer to FIG. 4).

The cell region R1 may include a word line, a bit line, and a capacitor. The cell region R1 is a memory cell region for storing data, and may be driven by selecting a word line and a bit line.

The cell region R1 may include a plurality of active regions 103 defined by the device isolation layer 102. Each active region 103 may have an island shape having a major axis and a minor axis. The active regions 103 may be spaced apart from each other by the device isolation layer 102 at a regular interval. The cell region R1 may include a bit line structure BL and the like which extend in a direction perpendicular to the word line and the word line composed of the buried gate structure BG, that is, in a direction of the major axis of the active region 103. The cell region R1 is a memory cell region for storing data, and may be driven by selecting a word line and a bit line.

The peripheral circuit region R2 may be formed around the cell region R1 and include a circuit region for driving and controlling the memory cell. In particular, the peripheral circuit region R2 according to an embodiment of the present invention may include a reservoir capacitor for filtering noise existing between various operating voltages such as the positive supply voltage VDD and the ground voltage VSS. In this embodiment, one reservoir capacitor is illustrated for convenience of description.

Referring to FIG. 4, the semiconductor device according to the embodiment of the present invention may include the cell region R1 and the peripheral circuit region R2.

The cell region R1 may include the buried gate structure BG disposed in the substrate 101 and the bit line structure BL formed on the substrate 101.

The buried gate structure BG may include a gate trench 105, a gate insulating layer 106 covering a bottom surface and sidewalls (also referred to as side surfaces) of the gate trench 105, a buried gate electrode 107 partially filling the gate trench 105 over the gate insulating layer 106, and a gate capping layer 108 formed over the buried gate electrode 107. Source/drain regions 109 and 110 may be formed in the substrate 101 on both sides of the buried gate structure BG.

The bit line structure BL may include a bit line contact plug 114, bit lines 118 and 119 over the bit line contact plug 114, and a bit line hard mask 120 over the bit lines 118 and 119. The bit line contact plug 114 may be connected to the source/drain region 109 which is formed between two adjacent buried gate structures BG.

The peripheral circuit region R2 may be separated from the cell region R1 by the device isolation layer 102. A reservoir capacitor of the peripheral circuit region R2 may include a substrate 101 including a plurality of peripheral trenches 112, a first electrode 114′ partially buried in the peripheral trenches 112 and having pillar shape protruding above the substrate 101, a first dielectric layer 113 disposed between the substrate 101 and the first electrode 114′, second electrode structure 117/1187119′ disposed over the substrate 101 and the first electrode 114′ and covering side surface and top surface of the first electrode 114′, a second dielectric layer 115 disposed between the first electrode 114′ and the second electrode structure 117/118′/119′, and a third dielectric layer 116 disposed between the substrate 101 and the second electrode structure 117/1187119′. In addition, the reservoir capacitor may include the substrate 101 and first to third interconnections ML1, ML2, and ML3 for applying a voltage to each electrode. The interconnections may be electrically connected to the substrate 101 and/or the electrodes through the first to third contacts CT1, CT2, and CT3.

The first dielectric layer 113 may be disposed between the substrate 101 and the first electrode 114′. The first dielectric layer 113 may include silicon oxide. The first dielectric layer 113 may be formed through a thermal oxidation process. The first dielectric layer 113 may be formed to cover side surfaces and a bottom surface of the trench 112. The first dielectric layer 113 formed on the side surface of the trench 112 may have an inclined profile that increases in thickness toward the bottom surface of the trench 112.

The first electrode 114′ may be disposed between the substrate 101 and the second electrode structure 117/118′/119′. The first electrodes 114′ may be configured to include a plurality of first electrodes 114′ spaced apart from each other at a regular interval. The first electrode 114′ may be spaced apart from the substrate 101 and the second electrode structure 117/118′/119′ by the first and second dielectric layers 113 and 115.

The second dielectric layer 115 may be disposed between the first electrode 114′ and the second electrode structure 117/118′/119′. The third dielectric layer 116 may be disposed between the substrate 101 and the second electrode structure 117/118′/119′. The second dielectric layer 115 and the third dielectric layer 116 may include silicon oxide. The second dielectric layer 115 and the third dielectric layer 116 may be simultaneously formed. The second dielectric layer 115 and the third dielectric layer 116 may be formed through a thermal oxidation process.

The second electrode structure 117/118′/119′ may include a conductive material. The second electrode structure (UE)/117/118′/119′ may include a stacked structure of a semiconductor material and a metal material.

The first to third interconnections ML1, ML2, and ML3 may be located at a higher level than the second electrode structure 117/118′/119′. The first to third interconnections ML1, ML2, and ML3 may be located at the same level or different levels. The first interconnection ML1 may be connected to the plurality of first electrodes 114′. The first contacts CT1 may electrically connect the first interconnection ML1 and the plurality of first electrodes 114′. The second interconnection ML2 may be connected to the second electrode structure 117/118′/119′. The second contact CT2 may electrically connect the second electrode structure 117, 118′ and 119′ and the second interconnection ML2. The third interconnection ML3 may be connected to the substrate 101. The third contact CT3 may electrically connect the third interconnection ML3 and the substrate 101. The third contact CT3 may contact the impurity region 120.

The capacitance of the reservoir capacitor according to the embodiment of the present invention may be the sum of the first capacitance C1 through the substrate 101, the first dielectric layer 113, and the first electrode 114′, the second capacitance C2 through the first electrode 114′, and the second dielectric layer 115, and the second electrode structure 117/1187119′, and the third capacitance C3 through the substrate 101, the third dielectric layer 116, and the second electrode structure 117/118′/119′.

The bit line contact plug 114 of the cell region R1 and the first electrode 114′ of the peripheral circuit region R2 may be located at the same level. The bit line contact plug 114 of the cell region R1 and the first electrode 114′ of the peripheral circuit region R2 may be formed of the same material. The bit line contact plug 114 and the first electrode 114′ may be simultaneously formed through a single gap fill process.

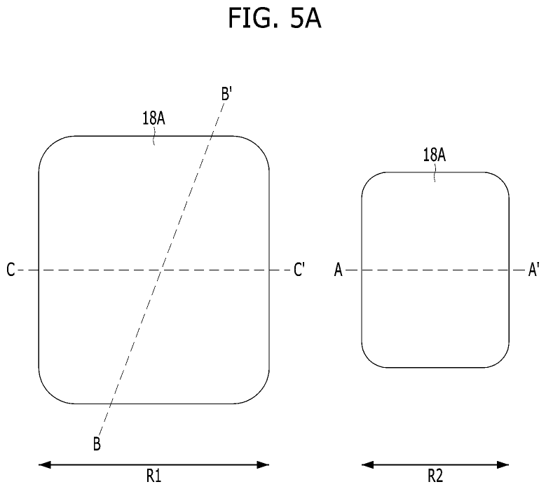

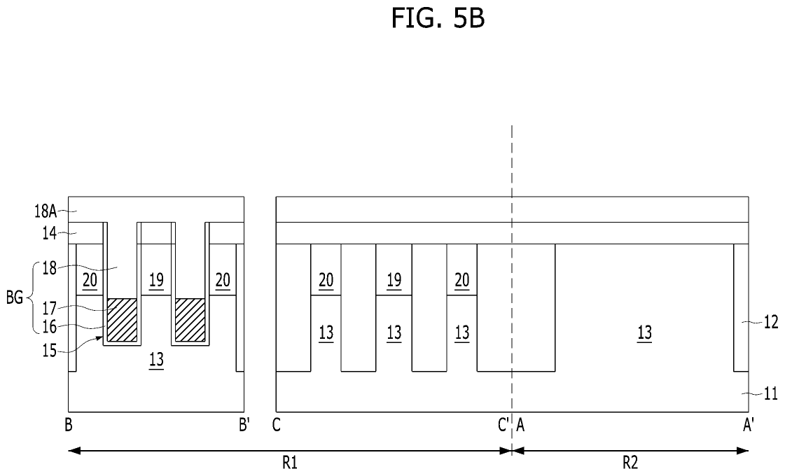

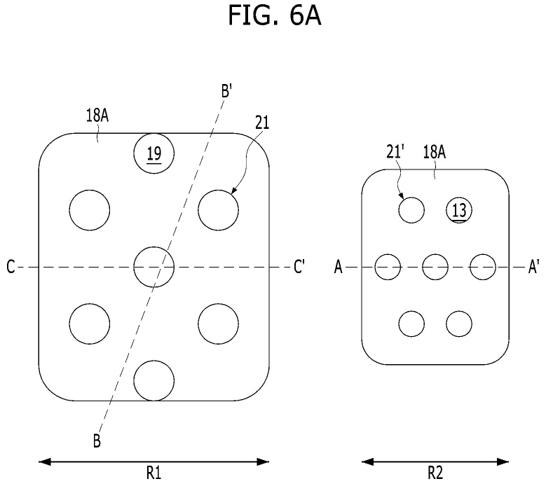

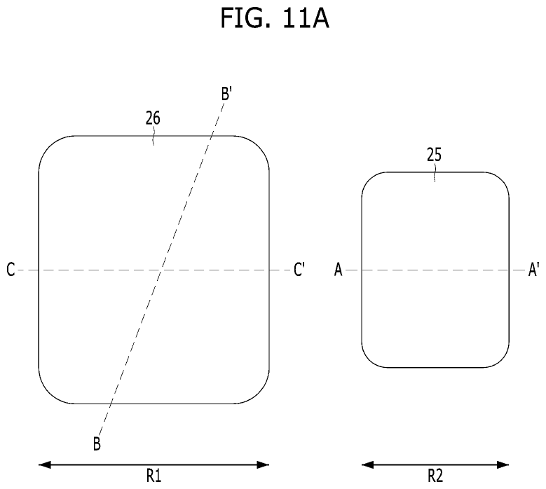

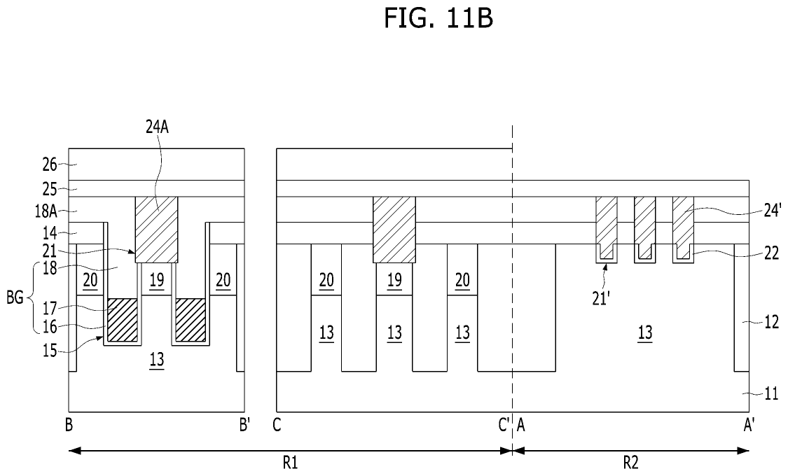

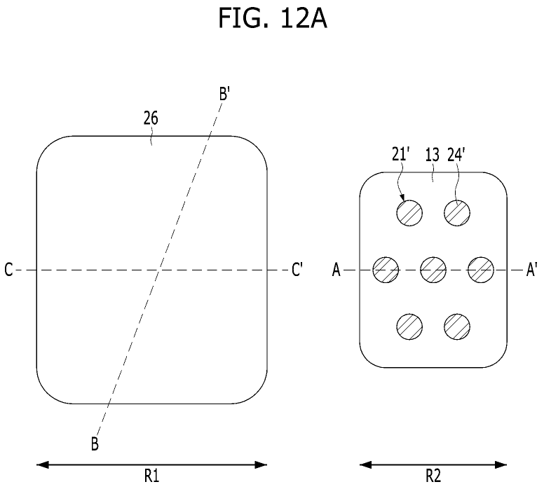

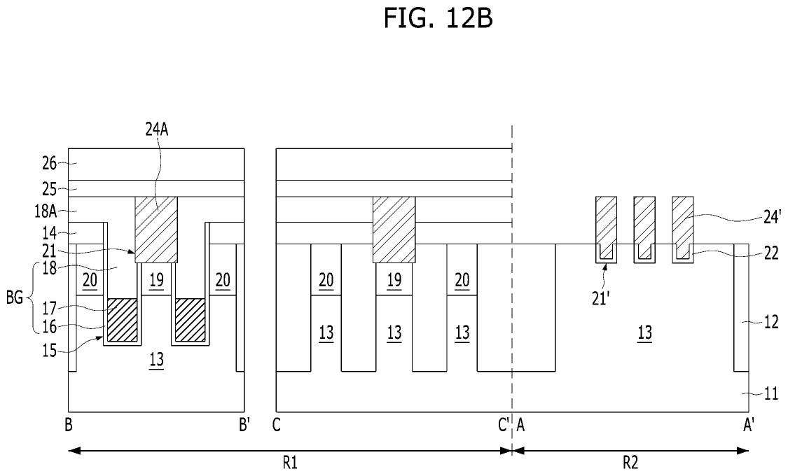

FIGS. 5A to 18B are plan views and cross-sectional views illustrating a method of fabricating a semiconductor device according to an embodiment of the present invention. In FIGS. 5A to 18B, each figure denoted with “A” is a plan view, and each figure denoted with “B” has cross-sectional views taken along the line A-A′, B-B′, and C-C′ of the figure denoted with A.

As shown in FIGS. 5A and 5B, a substrate 11 including a cell region R1 and a peripheral circuit region R2 may be provided.

The substrate 11 may include a device isolation layer 12 and an active region 13 defined by the device isolation layer 12. The active regions 13 may be spaced apart from each other at a regular interval by the device isolation layer 12. The cell region R1 and the peripheral circuit region R2 may be spaced apart by the device isolation layer 12.

The substrate 11 may be a material suitable for semiconductor processing. The substrate 11 may include a semiconductor substrate. The substrate 11 may be made of a material containing silicon. The substrate 11 may include silicon, monocrystalline silicon, polysilicon, amorphous silicon, silicon germanium, monocrystalline silicon germanium, polycrystalline silicon germanium, carbon doped silicon, combinations thereof, or multilayers thereof. The substrate 11 may include other semiconductor materials such as germanium. The substrate 11 may include a III/V group semiconductor substrate, for example, a compound semiconductor substrate such as gallium arsenide (GaAs). The substrate 11 may include a silicon on insulator (SOI) substrate.

The device isolation layer 12 may be formed by a shallow trench isolation (STI) process. The STI process may include etching the substrate 11 to form an isolation trench (reference numeral omitted). The isolation trench is then filled with an insulating material, and thus the device isolation layer 12 is formed. The device isolation layer 12 may include silicon oxide, silicon nitride, or a combination thereof. Chemical vapor deposition (CVD) or other deposition processes may be used to fill the isolation trench with an insulating material. A planarization process such as chemical mechanical polishing (CMP) may additionally be used.

Next, a buried gate structure BG may be formed in the substrate 11 of the cell region R1. The buried gate structure BG may include a gate trench 15, a gate insulating layer 16 covering the bottom surface and sidewalls of the gate trench 15, a buried gate electrode 17 partially filling the gate trench 15 over the gate dielectric layer 16, and a gate capping layer 18 formed over the buried gate electrode 17.

A method of forming the buried gate structure BG is as follows.

First, a gate trench 15 may be formed in the substrate 11 of the cell region R1. The gate trench 15 may have a line shape crossing the active regions 13 and the device isolation layer 12. The gate trench 15 may be formed by forming a mask pattern on the substrate 11 and an etching process using the mask pattern as an etching mask. In order to form the gate trench 15, the hard mask layer 14 may be used as an etch barrier. The hard mask layer 14 may have a shape patterned by a mask pattern. The hard mask layer 14 may cover the entire surface of the substrate in the peripheral circuit region R2. The hard mask layer 14 may include silicon oxide. The hard mask layer 14 may include tetra ethyl ortho silicate (TEOS). The bottom surface of the gate trench 15 may be at a higher level than the bottom surface of the device isolation layer 12.

A portion of the device isolation layer 12 of the cell region R1 may be recessed to protrude the active region 13 under the gate trench 15. The device isolation layer 12 under the gate trench 15 may be selectively recessed. Accordingly, a fin region under the gate trench 15 may be formed. The fin region may be a part of the channel region.

Next, a gate insulating layer 16 may be formed on the bottom surface and sidewalls of the gate trench 15. Before the gate insulating layer 16 is formed, the etch damage on the surface of the gate trench 15 may be cured. For example, after the sacrificial oxide is formed by thermal oxidation, the sacrificial oxide may be removed.

The gate insulating layer 16 may be formed by thermal oxidation. For example, the gate insulating layer 16 may be formed by oxidizing the bottom and sidewalls of the gate trench 15.

In another embodiment, the gate insulating layer 16 may be formed by a deposition method such as chemical vapor deposition (CVD) or atomic layer deposition (ALD). The gate insulating layer 16 may include a high-k material, oxide, nitride, oxynitride, or a combination thereof. A high-k material may include hafnium oxide. The hafnium-containing material may include hafnium oxide, hafnium silicon oxide, hafnium silicon oxynitride, or a combination thereof. In another embodiment, a high-k material may include lanthanum oxide, lanthanum aluminum oxide, zirconium oxide, zirconium silicon oxide, zirconium silicon oxynitride, aluminum oxide, and combinations thereof.

In another embodiment, the gate insulating layer 16 may be formed by depositing liner polysilicon and then radically oxidizing the liner polysilicon layer.

In another embodiment, the gate insulating layer 16 may be formed by radically oxidizing the liner silicon nitride layer after forming the liner silicon nitride layer.

Next, a buried gate electrode 17 may be formed on the gate insulating layer 16. To form the buried gate electrode 17, a recessing process may be performed after a conductive layer is formed to fill the gate trench 15. The recessing process may be performed as an etchback process, or as a chemical mechanical polishing (CMP) process and a subsequent etchback process. The buried gate electrode 17 may have a recessed shape that partially fills the gate trench 15. That is, the top surface of the buried gate electrode 17 may be at a lower level than the top surface of the active region 13. The buried gate electrode 17 may include a metal, a metal nitride, or a combination thereof. For example, the buried gate electrode 17 may be formed of a titanium nitride (TIN), tungsten (W), or a titanium nitride/tungsten (TiN/W) stack. The titanium nitride/tungsten (TiN/W) stack may have a structure in which titanium nitride is conformally formed and then the gate trench 15 is partially filled with tungsten. As the buried gate electrode 17, titanium nitride may be used alone, and this may be referred to as the buried gate electrode 17 having a “TiN Only” structure. A double gate structure of a titanium nitride/tungsten (TiN/W) stack and a polysilicon layer may be used as the buried gate electrode 17.

Next, capping layers 18 and 18A may be formed on the entire surface of the substrate including the buried gate electrode 17. The capping layers 18 and 18A may include an insulating material. The capping layers 18 and 18A may include silicon nitride. In another embodiment, the capping layers 18 and 18A may include silicon oxide. In another embodiment, the capping layers 18 and 18A may have a Nitride-Oxide-Nitride (NON) structure.

The capping layers 18 and 18A may be divided into a gate capping layer 18 that gap-fills the gate trench 15 on the buried gate electrode 17 and a protective capping layer 18A that covers the top surface of the hard mask layer 14. A buried gate structure BG may be formed by the gate insulating layer 16, the buried gate electrode 17, and the gate capping layer 18.

The top surface of the protective capping layer 18A may be at a higher level than the top surface of the hard mask layer 14. The protective capping layer 18A may cover both the hard mask layer 14 and the buried gate structure BG.

Next, source/drain regions 19 and 20 may be formed on the substrate 11 on both sides of the buried gate structure BG. The source/drain regions 19 and 20 may be formed by a doping process such as implantation. The source/drain region 19 may be formed between adjacent buried gate structures BG and may be a region to which a bit line contact plug is to be connected. The source/drain region 20 may be formed outside the buried gate structure BG between the buried gate structure BG and the device isolation layer 12 and may be a region to which a storage node contact plug is to be connected.

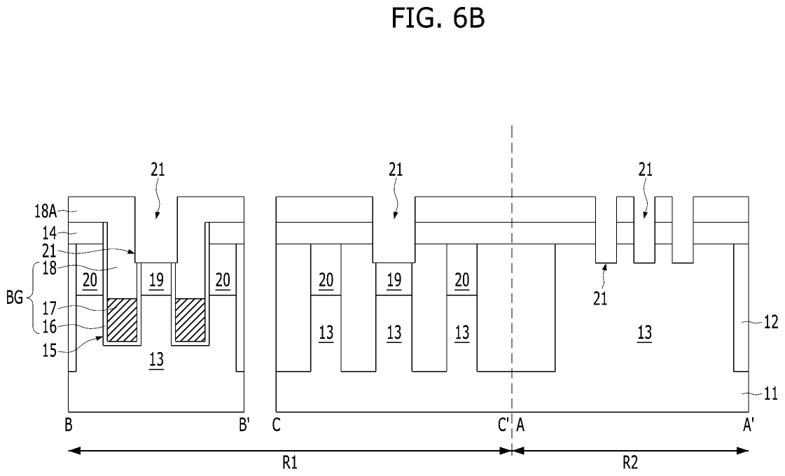

As shown in FIGS. 6A and 6B, a plurality of bit line contact holes 21 may be formed in the cell region R1, and a plurality of peripheral trenches 21′ may be formed in the peripheral circuit region R2.

The bit line contact hole 21 may be disposed between the adjacent buried gate structures BG. The peripheral trenches 21′ may be disposed to be spaced apart from each other by a regular interval in the active region 13 of the peripheral circuit region R2.

The protective capping layer 18A and the hard mask layer 14 may be etched by using a contact mask to form the bit line contact hole 21 and the peripheral trench 21′. The bit line contact hole 21 and the peripheral trench 21′ may be simultaneously formed. That is, the cell region R1 and the protective capping layer 18A and the hard mask layer 14 of the peripheral circuit region R2 may be simultaneously etched by using a contact mask which covers the cell region R1 and the peripheral circuit region R2 and defines the hole region and the peripheral trench region respectively in the cell region R1 and the peripheral circuit region R2. In another embodiment, the bit line contact hole 21 and the peripheral trench 21′ may be sequentially formed through respective mask processes.

A portion of the substrate 11 of the cell region R1 may be exposed through the bit line contact hole 21. The bit line contact hole 21 may have a diameter controlled to a predetermined line width. The bit line contact hole 21 may have a shape exposing a portion of the active region 13 of the cell region R1. The bit line contact hole 21 has a diameter greater than the width of the minor axis of the active region 13 of the cell region R1. Accordingly, in the etching process for forming the bit line contact hole 21, portions of the device isolation layer 12 and the active region 13 of the cell region R1 may be etched. That is, the device isolation layer 12 and the active region 13 under the bit line contact hole 21 may be recessed to a predetermined depth. Accordingly, the bottom of the bit line contact hole 21 may be extended into the substrate 11.

The substrate 11 of the peripheral circuit region R2 may be recessed to a predetermined depth by the peripheral trench 21′. In an embodiment of the present invention, the line width of the peripheral trench 21′ may be smaller than the line width of the bit line contact hole 21. In another embodiment, the line width of the peripheral trench 21′ may be the same as the line width of the bit line contact hole 21 or greater than the line width of the bit line contact hole 21. In this embodiment, a distance between adjacent peripheral trenches 21′ may be smaller than a distance between adjacent bit line contact holes 21. In another embodiment, a distance between adjacent peripheral trenches 21′ may be the same as a distance between adjacent bit line contact holes 21 or may be greater than a distance between bit line contact holes 21. The line width of the peripheral trench 21′, the depth of the peripheral trench 21′, and the number of the peripheral trenches 21′ disposed in the active region 13 of the peripheral circuit region R2 may be adjusted as needed.

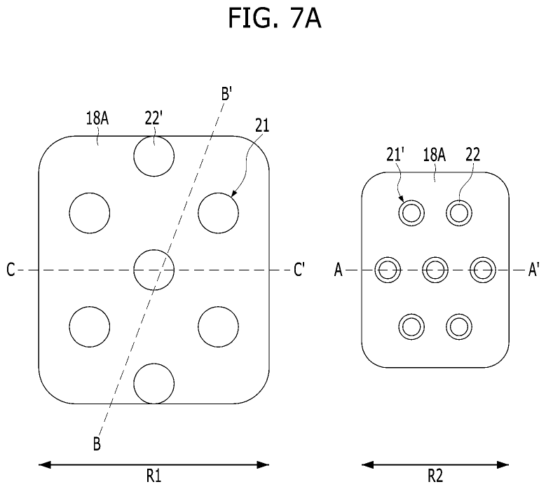

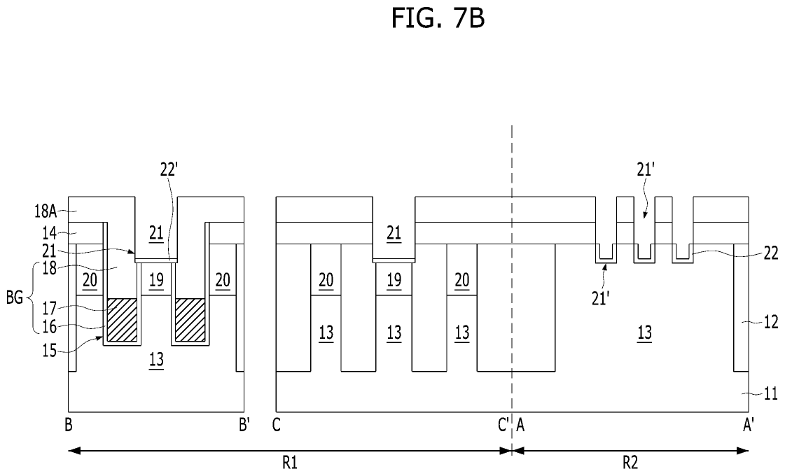

As shown in FIGS. 7A and 7B, a first dielectric layer 22 may be formed on the surface of the substrate 11 in the peripheral circuit region R2 exposed by the peripheral trench 21′. The first dielectric layer 22 may include silicon oxide. The first dielectric layer 22 may be formed through a thermal oxidation process. The first dielectric layer 22 may be formed through a rapid thermal annealing (RTA) process in an oxygen (O₂) atmosphere. The first dielectric layer 22 may be locally formed on the surface of the substrate 11 in the peripheral trench 21′. Although the first dielectric layer 22 is shown to have the same thickness on the bottom and sidewalls of the peripheral trench 21′, the thickness of the sidewall of the peripheral trench 22 may be thicker than the thickness of the bottom of the peripheral trench 21′. In another embodiment, the first dielectric layer 22 formed on the sidewall of the peripheral trench 21′ may have a slope profile that increases in thickness as it approaches the bottom.

In this case, the silicon oxide 22′ may also be formed on the surface of the substrate 11 of the cell region R1 exposed by the bit line contact hole 21.

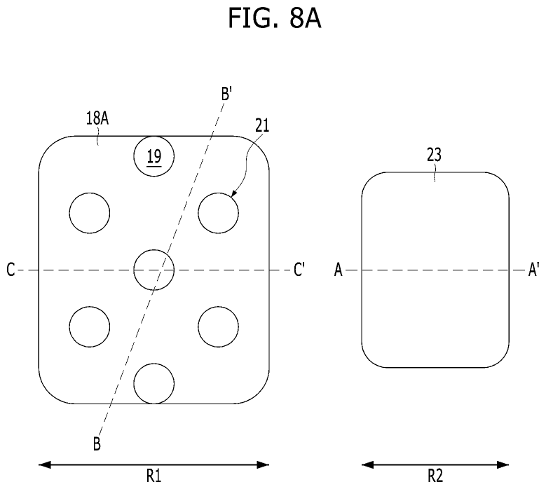

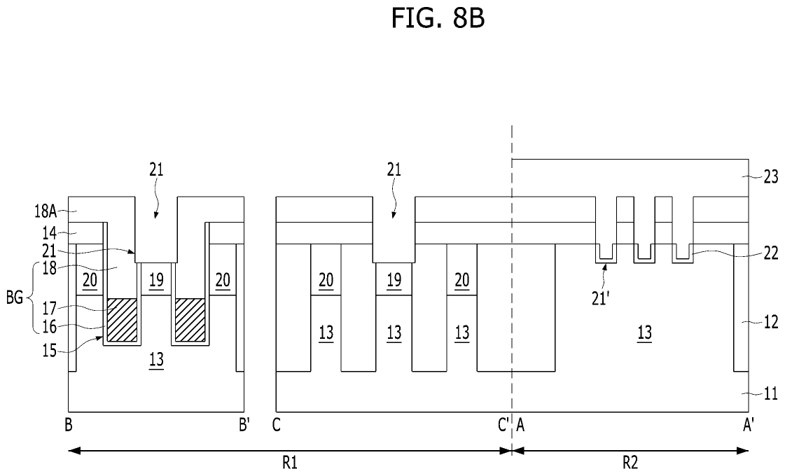

As shown in FIGS. 8A and 8B, the first cell open mask 23 may be formed. The first cell open mask 23 may cover structures of the peripheral circuit region R2. The first cell open mask 23 may include a photo resist.

Subsequently, the silicon oxide 22′ (refer to FIG. 6B) formed on the surface of the substrate 11 in the cell region R1 may be removed.

Subsequently, the first cell open mask 23 may be removed.

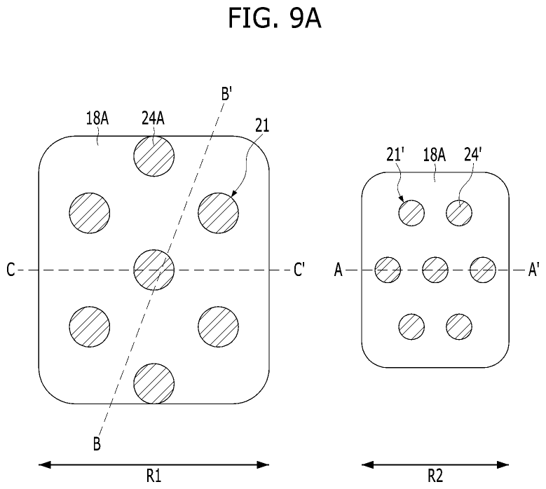

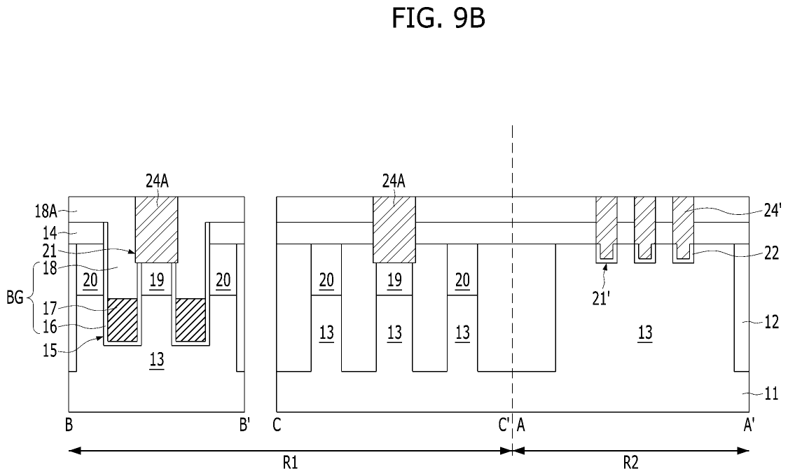

As shown in FIGS. 9A and 9B, a preliminary bit line contact plug 24A gap-filling the bit line contact hole 21 of the cell region R1 and the first electrode 24′ gap-filling the peripheral trench 21′ of the peripheral circuit region R2 may be formed.

The process of forming the preliminary bit line contact plug 24A and the first electrode 24′ is as follows.

First, a plug conductive layer may be formed on the bit line contact hole 21 and the protective capping layer 18A of the cell region R1, and the peripheral trench 21′ and the protective capping layer 18A of the peripheral circuit region R2 may be formed. The plug conductive layer may be applied to the bit line contact plug of the cell region R1 and the first electrode of the peripheral circuit region R2. The plug conductive layer may include a material having an etch selectivity with respect to the protective capping layer 18A. The plug conductive layer may include a silicon material. The plug conductive layer may include polysilicon. The plug conductive layer may include polysilicon doped with impurities.

Subsequently, the plug conductive layer may be etched so that the plug conductive layer remains in the bit line contact hole 21 of the cell region R1 and the peripheral trench 21′ of the peripheral circuit region R2. The plug conductive layer may be etched through an etch-back process or a CMP process. The etch stop target of the plug conductive layer may be the protective capping layer 18A. That is, the etching process may be performed until all the plug conductive layers on the protective capping layer 18A are removed. After the etching process, a cleaning process may be performed.

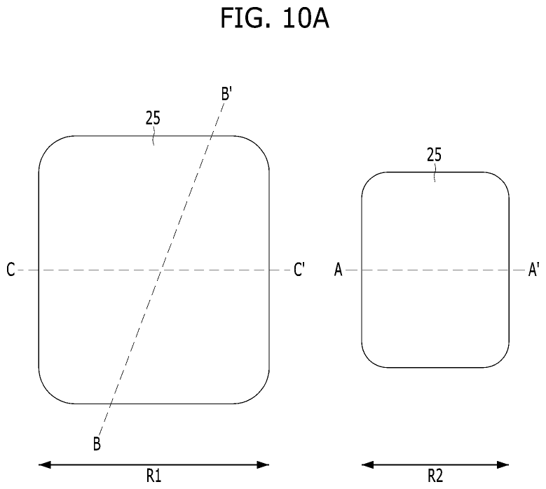

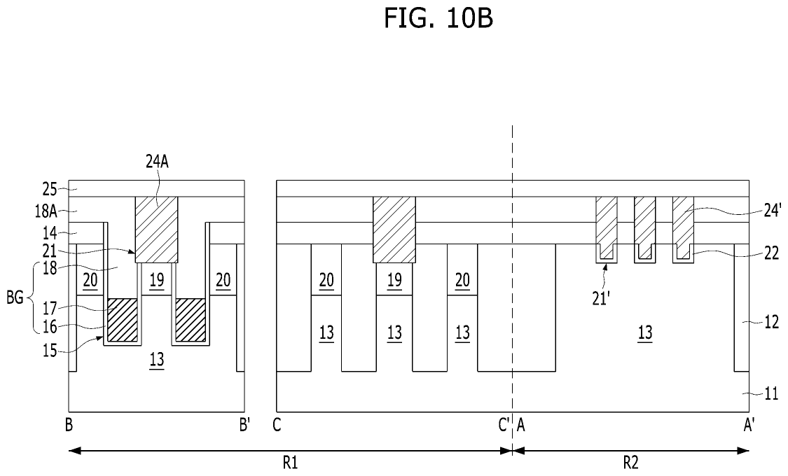

As shown in FIGS. 10A to 12B, a cell protection layer 25 may be formed for covering the preliminary bit line contact plug 24A, and the protective capping layer 18A of the cell region R1 and the protective capping layer 18A of the peripheral circuit region R2. The cell protection layer 25 may serve to prevent oxidation of the preliminary bit line contact plug 24A of the cell region R1. The cell protection layer 25 may include an insulating material. The cell protection layer 25 may include silicon nitride.

Subsequently, a peripheral open mask 26 may be formed on the cell protection layer 25 of the cell region R1. The cell protection layer 25 of the peripheral circuit region R2 may be exposed by the peripheral open mask 26. The peripheral open mask 26 may include a photoresist.

Subsequently, the cell protection layer 25 of the peripheral circuit region R2 may be etched by using the peripheral open mask 26.

Accordingly, in the peripheral circuit region R2, the first electrode 24′ and the protective capping layer 18A may be exposed.

Subsequently, the protective capping layer 18A and the hard mask layer 14 of the peripheral circuit region R2 may be etched by using the peripheral open mask 26. Accordingly, the surface of the substrate 11 may be exposed in the peripheral circuit region R2. A portion of the first electrode 24′ may be buried in the substrate 11 and a remainder may have a pillar shape protruding above the substrate 11.

Subsequently, the peripheral open mask 26 may be removed.

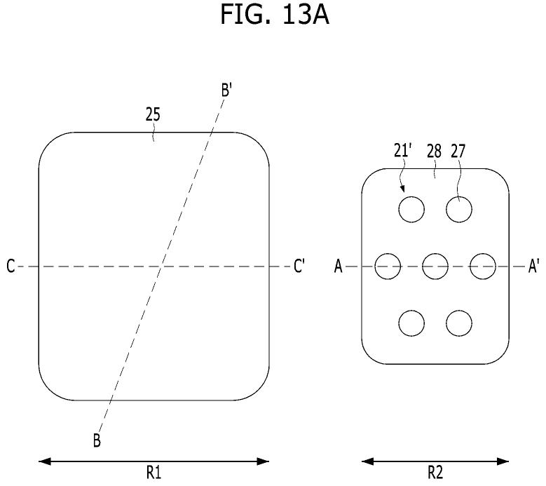

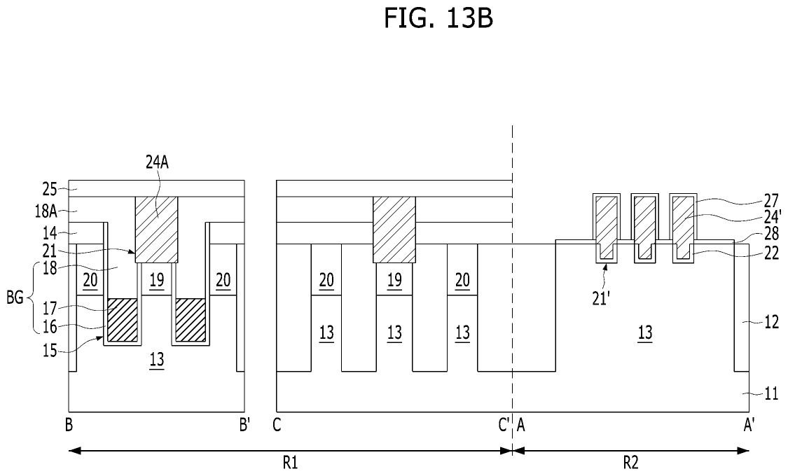

As shown in FIGS. 13A and 13B, a second dielectric layer 27 covering the top surface and side surface of the first electrode 24′ and a third dielectric layer 28 covering the exposed surface of the substrate 11 of the peripheral circuit region R2 may be formed.

The second dielectric layer 27 and the third dielectric layer 28 may include silicon oxide. The second dielectric layer 27 and the third dielectric layer 28 may be simultaneously formed through a thermal oxidation process. The second dielectric layer 27 and the third dielectric layer 28 may be formed through a rapid thermal annealing (RTA) process in an oxygen (O₂) atmosphere.

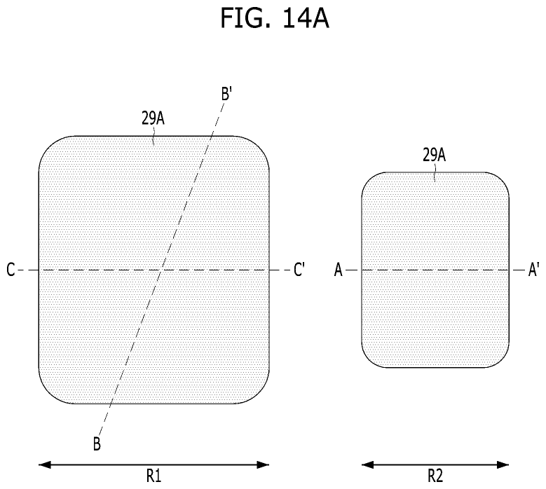

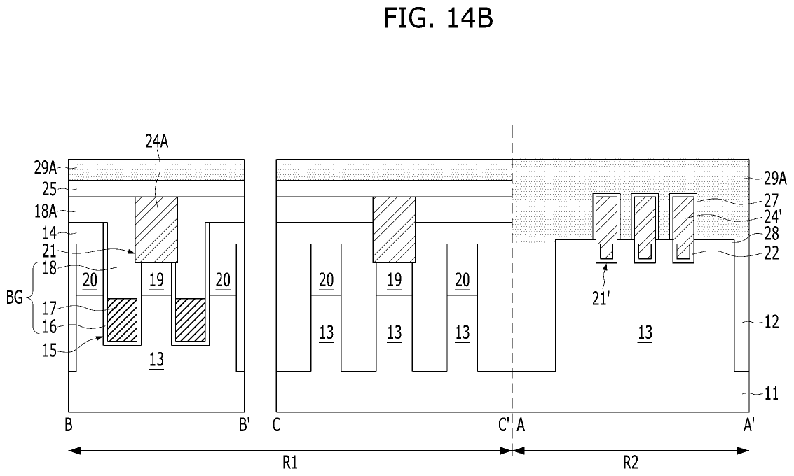

As shown FIGS. 14A and 14B, a peripheral conductive layer 29A may be formed on the cell protection layer 25 of the cell region R1 and on the second and third dielectric layers 27 and 28 of the peripheral circuit region R2. The peripheral conductive layer 29A may be formed to have a top surface at least at a level higher than an top surface of the first electrode 24′. The peripheral conductive layer 29A may include a silicon material. The peripheral conductive layer 29A may include polysilicon. The peripheral conductive layer 29A may include polysilicon doped with impurities.

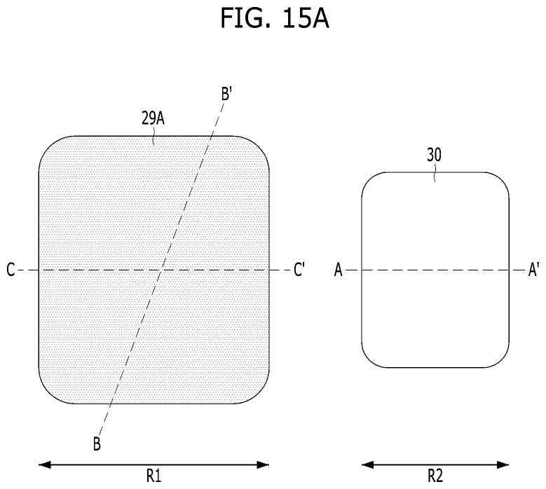

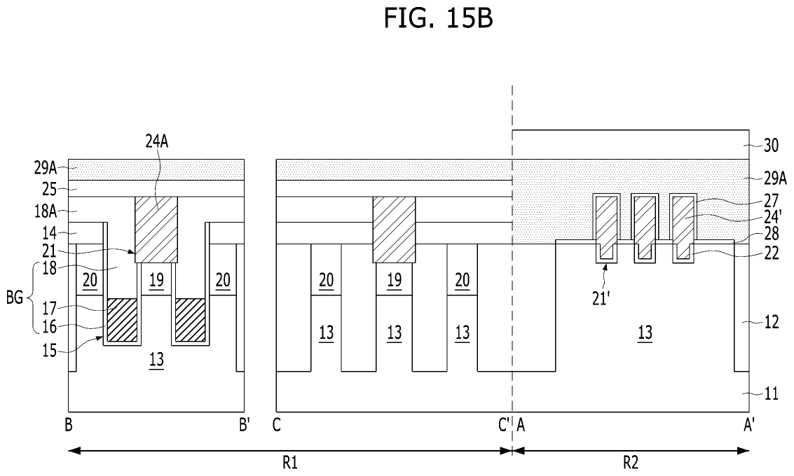

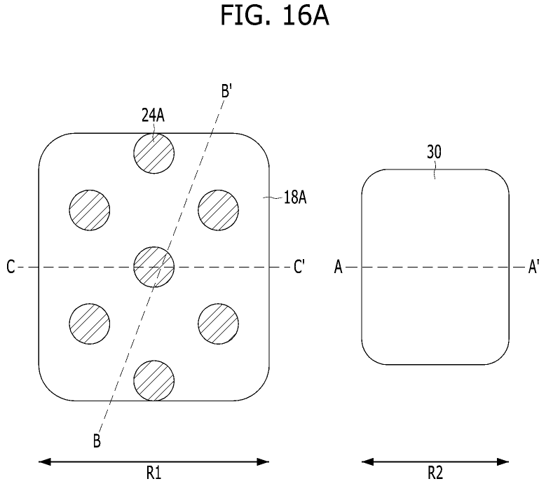

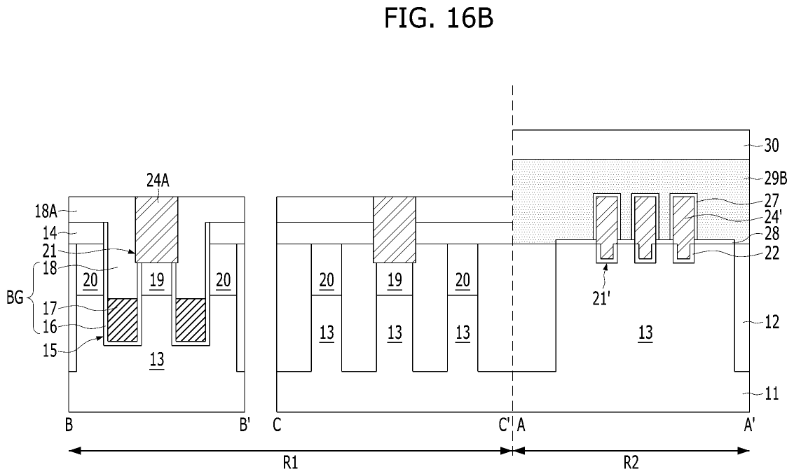

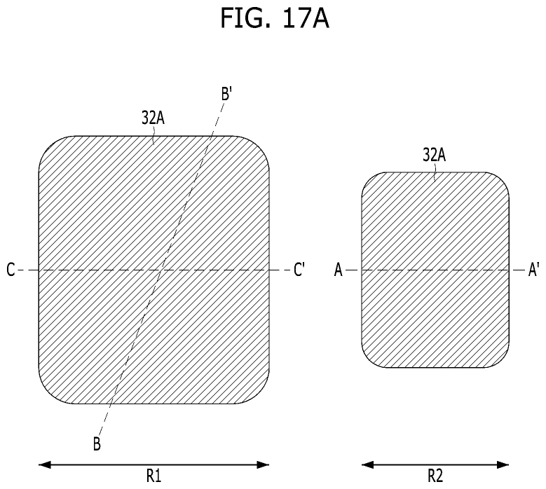

As shown in FIGS. 15A to 16B, a second cell open mask 30 may be formed on the peripheral conductive layer 29A of the peripheral circuit region R2. The peripheral conductive layer 29A of the cell region R1 may be exposed by the second cell open mask 30. The second cell open mask 30 may include a photoresist.

Subsequently, the peripheral conductive layer 29A and the cell protection layer 25 of the cell region R1 may be etched by using the second cell open mask 30. Accordingly, the peripheral conductive layer 29B may remain only in the peripheral circuit region R2.

Accordingly, in the cell region R1, the protective capping layer 18A and the preliminary bit line contact plug 24A may be exposed.

The preliminary bit line contact plug 24A may be recessed to a predetermined depth so that the top surface of the preliminary bit line contact plug 24A is disposed at a level lower than the top surface of the protective capping layer 18A.

Subsequently, the second cell open mask 30 may be removed.

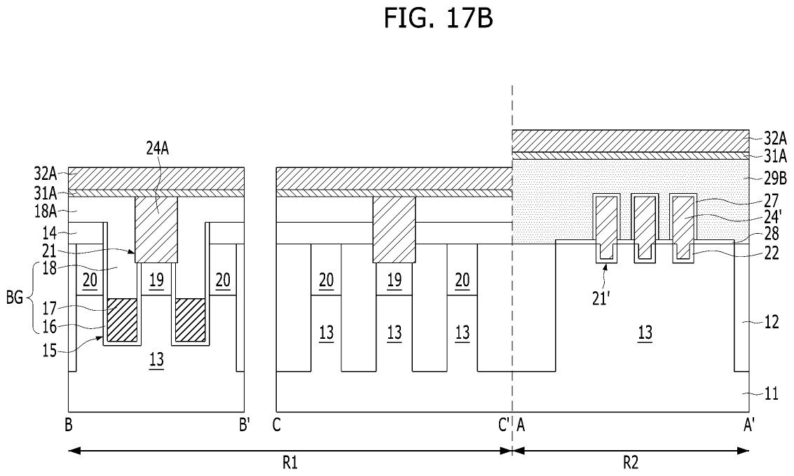

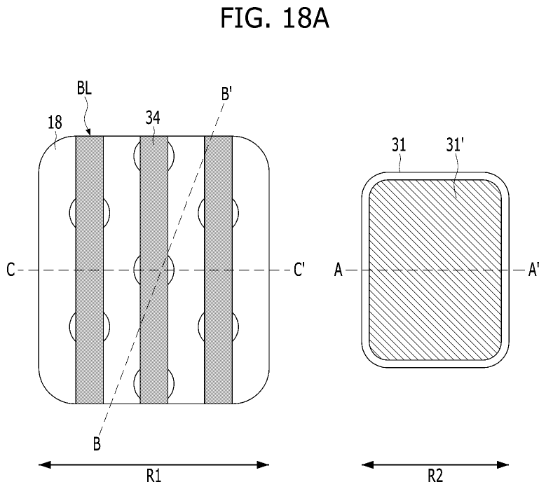

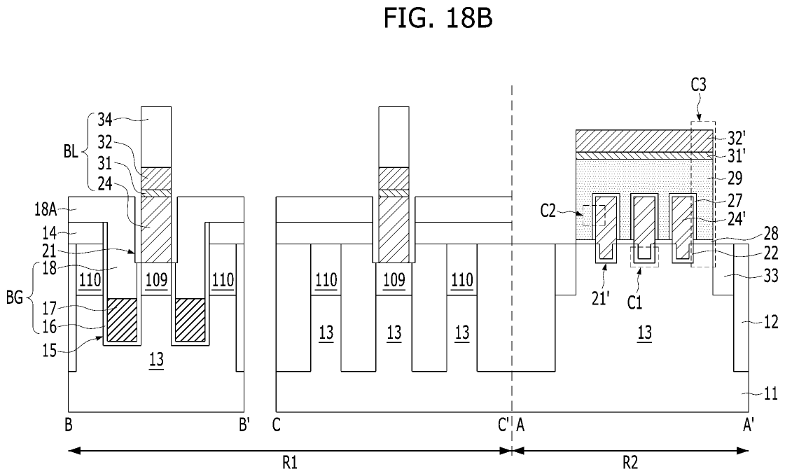

As shown in FIGS. 17A to 18B, the bit line conductive layers 31A and 32A may be formed on the protective capping layer 18A and the preliminary bit line contact plug 24A of the cell region R1 and the peripheral conductive layer 29B of the peripheral circuit region R2. The bit line conductive layers 31A and 32A may serve as a bit line in the cell region R1 and as a second electrode in the peripheral circuit region R2. The bit line conductive layers 31A and 32A may include a metal-containing material. The bit line conductive layers 31A and 32A may include a metal, a metal nitride, a metal silicide, or a combination thereof. For example, the bit line conductive layers 31A and 32A may include a stacked structure of a barrier layer 31A and an electrode layer 32A.

The barrier layer 31A may be formed of multiple layers. For example, the barrier layer 31A may have a stacked structure of a titanium layer (Ti), tungsten nitride (WN), and tungsten silicon nitride (WSiN). For example, the electrode layer 32A may include tungsten (W). The titanium layer (Ti) may serve as an adhesive layer. In addition, by forming the lower peripheral conductive layer 29B and the silicide (TiSi), it is possible to prevent the formation of silicon nitride between the tungsten nitride (WN) layer and the peripheral conductive layer 29B. The tungsten nitride (WN) layer may serve to prevent diffusion of tungsten (W) from the electrode layer 32A to the lower peripheral conductive layer 29B. In addition, the lower titanium (Ti) layer and titanium nitride (TiN) may be formed to prevent boron from diffusing upward from the lower peripheral conductive layer 29B. The tungsten nitride (WN) layer may serve as a seed layer for increasing the grain of the electrode layer 32A. That is, by forming the tungsten (W) layer on the tungsten nitride (WN) layer, the grain of the tungsten layer increases, thereby reducing the resistance of the electrode layer 32A.

Subsequently, the bit line structure BL composed of the bit line contact plug 24, the bit lines 31 and 32, and the bit line hard mask 34 may be formed in the cell region R1, and a reservoir capacitor including the second electrode structure 29, 31′, and 32′ may be formed in the peripheral circuit region R2.

The process of forming the bit line structure BL of the cell region R1 and the reservoir capacitor of the peripheral circuit region R2 is as follows.

First, a peripheral mask may be formed. The peripheral mask may cover the entire cell region R1 over the bit line conductive layer 32A of the cell region R1 and the peripheral circuit region R2 and define a reservoir capacitor region in the peripheral circuit region R2.

Subsequently, the bit line conductive layers 32A and 31A, the peripheral conductive layer 29B, and the third dielectric layer 28 of the peripheral circuit region R2 exposed by the peripheral mask may be etched.

Accordingly, the peripheral circuit region R2 may include the substrate 11 including the plurality of peripheral trenches 21′, the second electrode structure 29, 31′ and 32′ disposed on the substrate 11, the first to third dielectric layers 22, 27, 28 disposed between the substrate 11 and the second electrode structure 29, 31′, 32′, and a reservoir capacitor. The reservoir capacitor may be partially buried in the peripheral trench 21′ and include the first electrode 24′ of a pillar shape that protrudes above the substrate 11.

The first electrode 24′ may be disposed between the substrate 11 and the second electrode structure 29, 31′, and 32′. The first electrode 24′ may be configured to include a plurality of first electrodes, and may be disposed to be spaced apart from each other at a regular interval. The first electrode 24′ may be spaced apart from the substrate 11 and the second electrode structure 29, 31′ and 32′ by the first and second dielectric layers 22 and 27.

The first dielectric layer 22 may be disposed between the substrate 11 and the first electrode 24′. The second dielectric layer 27 may be disposed between the first electrode 24′ and the second electrode structure 29, 31′, and 32′. The third dielectric layer 28 may be disposed between the substrate 11 and the second electrode structure 29, 31′, and 32′.

The capacitance of the reservoir capacitor according to the present embodiment may be the sum of the first capacitance C1 through the substrate 11, the first dielectric layer 22, and the first electrode 24′, the second capacitance C2 through the first electrode 24′, the second dielectric layer 27, and the second electrode structure 29, 31′ and 32′, and the third capacitance C3 through the substrate 11, the third dielectric layer 28, and the second electrode structure 29, 31′, and 32′. The number of the first electrodes included in a single reservoir capacitor and the height and line width of each first electrode may be adjusted as needed.

Next, impurity regions 33 may be formed in the substrate 11 on both sides of the reservoir capacitor.

Subsequently, a cell mask that covers the entire peripheral circuit region R2 and defines a bit line region may be formed in the cell region R1. Before forming a cell mask, a bit line hard mask layer may be formed on the bit line conductive layers 31A and 32A of the cell region R1.

Subsequently, the bit line hard mask layer, bit line conductive layers 31A and 32A, and the preliminary bit line contact plug 24A may be sequentially etched by using a cell mask.

Accordingly, the bit line structure BL including the bit line contact plug 24, the bit lines 31 and 32, and the bit line hard mask 34 may be formed in the cell region R1.

As a subsequent process, a capacitor may be formed over the bit line structure BL of the cell region R1, and metal interconnections may be formed over the capacitor in the cell region R1 and the reservoir capacitor in the peripheral circuit region R2. The metal interconnections may be connected to the capacitor and the reservoir capacitor, respectively. In this case, the metal interconnection connected to the reservoir capacitor of the peripheral circuit region R2 may include the interconnections illustrated in FIGS. 1 and 2.

Various embodiments for the problem to be solved above have been described, but it will be apparent to those skilled in the art that various changes and modifications can be made within the scope of the technical spirit of the present invention.

What is claimed is:

1. A reservoir capacitor comprising:
a substrate;
a first electrode having a pillar shape and disposed over the substrate;
a first dielectric layer disposed between the substrate and the first electrode;
a second electrode disposed over the substrate and the first electrode and covering a side surface and a top surface of the first electrode;
a second dielectric layer disposed between the first electrode and the second electrode; and
a third dielectric layer disposed between the substrate and the second electrode.

2. The reservoir capacitor of claim 1,
wherein the substrate includes at least one trench.

3. The reservoir capacitor of claim 2,
wherein the first electrode is partially buried in the at least one trench and has a pillar shape protruding above the substrate.

4. The reservoir capacitor of claim 1, wherein the first electrode has a smaller line width than that of the second electrode.

5. The reservoir capacitor of claim 1, wherein the top surface of the first electrode is located at a lower level than a top surface of the second electrode.

6. The reservoir capacitor of claim 1, wherein a bottom surface of the first electrode is located at a lower level than a top surface of the substrate.

7. The reservoir capacitor of claim 1, wherein the first electrode is configured in plurality and spaced apart from each other.

8. The reservoir capacitor of claim 1, wherein the first electrode includes polysilicon.

9. The reservoir capacitor of claim 1, wherein the second electrode includes a stack structure of polysilicon and a metal material.

10. The reservoir capacitor of claim 1, wherein the second and third dielectric layers are a continuous single layer.

11. The reservoir capacitor of claim 1, wherein the first and third dielectric layers include silicon oxide.

12. The reservoir capacitor of claim 1, further including an impurity region in the substrate on both sides of the reservoir capacitor.

13. The reservoir capacitor of claim 1, further including:
first to third interconnections located at a higher level than the second electrode;
a first plug electrically connecting the first interconnection and the first electrode;
a second plug electrically connecting the second interconnection and the second electrode; and
a third plug electrically connecting the third interconnection and the substrate.

14. A reservoir capacitor comprising:
a substrate including an active region defined by a device isolation layer and the device isolation layer;
a plurality of trenches formed in the substrate and spaced apart from each other;
a first dielectric layer covering a bottom surface and a sidewall of the trenches;
a plurality of first electrodes partially buried in the trenches over the first dielectric layer and having a pillar shape protruding above the substrate;
a second dielectric layer covering top surface and side surface of each of the first electrodes;
a third dielectric layer covering a portion of the substrate exposed between the first electrodes; and
a second electrode formed over the second and third dielectric layers.

15. The reservoir capacitor of claim 14, wherein the plurality of the first electrodes are spaced apart at a regular interval in the active region of the substrate.

16. The reservoir capacitor of claim 14, wherein the first electrode has a smaller line width than that of the second electrode.

17. The reservoir capacitor of claim 14, wherein the top surfaces of the first electrodes are located at a lower level than a top surface of the second electrode.

18. The reservoir capacitor of claim 14, wherein a bottom surface of each of the first electrodes is located at a lower level than a top surface of the substrate.

19. The reservoir capacitor of claim 14, wherein the first electrodes include polysilicon.

20. The reservoir capacitor of claim 14, wherein the second electrode includes a stack structure of polysilicon and a metal material.

21. The reservoir capacitor of claim 14, wherein the second and third dielectric layers are a continuous single layer.

22. The reservoir capacitor of claim 14, wherein the first to third dielectric layers include silicon oxide.

23. The reservoir capacitor of claim 14, further including an impurity region in the substrate on both sides of the reservoir capacitor.

24. The reservoir capacitor of claim 14, further including:
first to third interconnections located at a higher level than the second electrode;
a first plug electrically connecting the first interconnection and the first electrode;
a second plug electrically connecting the second interconnection and the second electrode; and
a third plug electrically connecting the third interconnection and the substrate.

25. A semiconductor device comprising:
a substrate including a cell region and a peripheral circuit region;
a bit line structure including a bit line contact plug over the substrate of the cell region;
a first electrode having a pillar shape and disposed over the substrate of the peripheral circuit region;
a second electrode disposed over the substrate and the first electrode in the peripheral circuit region and covering a side surface and a top surface of the first electrode;
a second dielectric layer disposed between the first electrode and the second electrode; and
a third dielectric layer disposed between the substrate and the second electrode.

26. The semiconductor device of claim 25, wherein the bit line contact plug and the first electrode are located at a same level.

27. The semiconductor device of claim 25, wherein the substrate includes at least one trench.

28. The semiconductor device of claim 27, wherein the first electrode is partially buried in the trench and has a pillar shape protruding above the substrate.

29. The semiconductor device of claim 25, wherein the first electrode has a line width smaller than that of the second electrode.

30. The semiconductor device of claim 25, wherein the top surface of the first electrode is located at a lower level than a top surface of the second electrode.

31. The semiconductor device of claim 25, wherein a bottom surface of the first electrode is located at a lower level than a top surface of the substrate.

32. The semiconductor device of claim 25, wherein the first electrode includes polysilicon.

33. The semiconductor device of claim 25, wherein the second electrode includes a stack structure of polysilicon and a metal material.

34. The semiconductor device of claim 25, wherein the second and third dielectric layers are a continuous single layer.

35. The semiconductor device of claim 25, further including an impurity region in the substrate on both sides of the reservoir capacitor.

36. The semiconductor device of claim 25, further including:
first to third interconnections located at a higher level than the second electrode;
a first plug electrically connecting the first interconnection and the first electrode;
a second plug electrically connecting the second interconnection and the second electrode; and
a third plug electrically connecting the third interconnection and the substrate.

37. The semiconductor device of claim 25, further including a buried gate structure formed in the substrate of the cell region.

38. The semiconductor device of claim 25, further including:
a capacitor disposed over the bit line structure in the cell region and connected to the substrate; and
a metal interconnection disposed over the capacitor and connected to the capacitor.

39. A method of fabricating a semiconductor device, the method comprising:
forming a capping layer over a substrate, the substrate including a cell region and a peripheral circuit region;
forming a bit line contact hole exposing the substrate by penetrating through the capping layer of the cell region and a peripheral trench exposing the substrate by penetrating through the capping layer of the peripheral circuit region;
forming a preliminary bit line contact plug and a first electrode by gap-filling a conductive material in the bit line contact hole and the peripheral trench;
forming a reservoir capacitor over the substrate of the peripheral circuit region, the reservoir capacitor including the first electrode having a pillar shape; and
forming a bit line structure over the substrate of the cell region, the bit line structure including a bit line contact plug.

40. The method of claim 39, after the forming of the peripheral trench, further including:
forming a first dielectric layer covering a bottom surface and a sidewall of the peripheral trench.

41. The method of claim 39, wherein the forming of the reservoir capacitor includes:
leaving the first electrode of pillar shape behind by removing the capping layer of the peripheral circuit region;
forming a second dielectric layer covering a top surface and a sidewall of the first electrode;
forming a third dielectric layer covering a top surface of the substrate of the peripheral circuit region;
forming a conductive material over the first and second dielectric layers; and
etching portions of the conductive material and the third dielectric layer.

42. The method of claim 39, before the forming of the capping layer, further including:
forming a buried gate structure in the substrate of the cell region.
